(19) United States
(12) Patent Application Publication
(10) Pub. No.: US 2008/0090157 A1
(43) Pub. Date: Apr. 17, 2008

(54) PHOTO MASK WITH IMPROVED CONTRAST AND METHOD OF FABRICATING THE SAME

(75) Inventors: Dong-Hoon CHUNG, Gyeonggi-do (KR); Sung-Min HUH, Gyeonggi-do (KR); Sung-Hyuck KIM, Gyeonggi-do (KR); Gi-Sung YOON, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/869,576

(22) Filed: Oct. 9, 2007

(30) Foreign Application Priority Data
Oct. 16, 2006 (KR) 2006-0100385

(51) Int. Cl. G03F 1/00

(52) U.S. Cl. 430/5

(57) ABSTRACT

A photo mask which enhances contrast and a method of fabricating the same are provided. The photo mask includes a transparent substrate and a light shielding layer pattern formed on the transparent substrate. The light shielding layer pattern includes apertures through which the transparent substrate is exposed. Depressions aligned with these apertures extend into the transparent substrate. Light exposed at an angle through the transparent layer would then pass into the depressions and reflect or diffuse from the sidewalls of the depressions and out through the apertures. The etching depth of the depressions is preferably equal to or less than a depth at which threshold intensity of the exposure light is saturated as the etching depth is increased. In another embodiment, the etching depth of the depressions is less than the wavelength of the exposure light.

### CROSS-REFERENCE TO RELATED PATENT APPLICATION

This application claims the benefit of Korean Patent Application No. 10-2006-0100385, filed on Oct. 16, 2006, in the Korean Intellectual Property Office, the disclosure of which is incorporated herein in its entirety by reference.

### BACKGROUND OF THE INVENTION

1. Field of the Invention

The present invention relates to a photo mask and a method of fabricating the same, and more particularly, to a photo mask for a projection stepper which is used to form a micro pattern on a wafer in a semiconductor device fabrication process, and a method of fabricating the same.

2. Description of the Related Art

Photolithography is generally used to form a pattern on a semiconductor wafer in a semiconductor device fabrication process. Photolithography involves forming a pattern image on a photo mask, transferring the pattern to a wafer coated with photosensitive resin using an exposure light in a reduction projection stepper, and developing the coated wafer, thereby obtaining a predetermined pattern. The photo mask corresponds to the original circuit pattern and is an important factor in determining the resolution of the pattern image which is transferred to the wafer.

FIG. 1 is a sectional view of a conventional binary mask and a schematic view of a near field image when exposure light passes through a photo mask.

The conventional binary photo mask shown in FIG. 1 comprises: a substrate having sufficient transparency to transmit the substantially all of the exposure light, and a light shielding layer. One example of the transparent substrate is quartz substrate 10. A common example of a light shielding layer is a patterned layer formed of chromium. Apertures 14 are defined by the light shielding layer pattern 12 and expose the transparent substrate 10. The shape of the apertures 14 defines the pattern image to be transferred. The exposure light (not shown) is incident on the photo mask from an upper portion relative to FIG. 1. When the incident exposure light passes through the apertures 14 of the transparent substrate 10, part of a photosensitive resin layer on a wafer (not shown) under the photo mask is exposed to the light. The exposed part corresponds to the pattern image formed on the photo mask.

As circuit feature sizes decrease, the spacing between adjacent apertures 14 becomes smaller. And because of diffraction between closely spaced apertures when exposed to light, it is difficult to separate adjacent pattern images from each other. That is, the light through one aperture interferes with the exposure light passing through the adjacent apertures 14. Consequently, the resolution of the pattern images is considerably decreased.

One solution proposed for this binary photo mask diffraction problem includes using a phase shift mask (PSM). The PSM gives high resolution by using a phase shift effect of the mask. The phase shift effect is obtained by using characteristics of the material on a photo mask or by changing the structure of the mask, without changing the light source of the conventional stepper.

FIG. 2 is a sectional view of a conventional attenuated PSM. Unlike the conventional chromium binary mask, the attenuated PSM gives high resolution by inserting a shift material, which transmits a predetermined light, between the light shielding layer formed of chromium and the transparent quartz substrate. Alternately, one may use a shift material with a predetermined transparency (e.g. a molybdenum series material) as a light shielding layer, instead of chromium. As distinguished from FIG. 1, FIG. 2 shows a light shielding layer 13 of the molybdenum series material formed on the transparent substrate 10, instead of the light shielding layer 12 formed of chromium in FIG. 1. As with light shielding layer 12 and apertures 14, the light shielding layer 13 defines apertures 24.

One drawback to using a shift material (such as molybdenum) with the PSM is that exposures may cause undesired side lobes. To combat this problem, process engineers have developed two process steps. However, these additional process steps increase the turn-around time and decrease the production yield using the molybdenum-based phase shift mask. Moreover, since molybdenum cannot be cleaned using sulphuric acid, the PSM is vulnerable to haze compared to the binary mask. And to prevent haze build-up, the mask may be periodically cleaned. However, this also can cause many potential problems.

Accordingly, the need exists for photo masks that address problems inherent in the prior art.

### SUMMARY OF THE INVENTION

According to an aspect of the present invention, there is provided a photo mask, which comprises a transparent substrate having transparency to an exposure light; and a light shielding layer pattern formed on the transparent substrate. The transparent substrate includes depressions formed in the transparent substrate, where the depressions have a uniform and predetermined etching depth aligned with the light shielding layer pattern. In preferred embodiments, the etching depth of the depressions is equal to or less than a depth at which threshold intensity of the exposure light is saturated as the etching depth is increased.

In accordance with another embodiment of the present invention, there is provided a photo mask, which comprises a transparent substrate having transparency to an exposure light; and a light shielding layer pattern formed on the transparent substrate. The transparent substrate includes depressions formed in the transparent substrate, where the depressions have a uniform and predetermined etching depth aligned with the light shielding layer pattern. In alternate embodiments, the etching depth of the depressions is equal to or less than a wavelength of the exposure light. Furthermore, the etching depth of the depressions may be equal to or less than a depth at which the ratio of a first order light to a zero order light (A₁/A₀) peaks in a near field image of the photo mask.

In the embodiments, the exposure light may use a light source having different wavelengths, for example, any one of G-line, I-line, KrF, ArF and F₂. The transparent substrate may be formed of another transparent material, for example, calcium fluoride (CaF₂) or magnesium fluoride (MgF₂), instead of quartz (SiO₂). The light shielding layer pattern may be formed of a material having light shielding characteristics, for example, chromium oxide (CrOₓ) or tungsten silicon (W—Si), instead of chromium. The photo mask patterns may be of various types, for example, a line/space type pattern in which lines and spaces are periodically repeated, an isolated line pattern, an isolated space pattern, or an island type pattern.

According to another aspect of the present invention, there is provided a method of fabricating a photo mask, comprising: forming a light shielding layer, which blocks an exposure light, on a transparent substrate having transparency to the exposure light; forming a mask pattern on the light shielding layer, to expose parts of the light shielding layer; forming a light shielding layer pattern by etching the exposed light shielding layer, using the mask pattern as an etching mask; and forming depressions within by etching parts of the transparent substrate, using the light shielding layer pattern as an etching mask, wherein the depressions have a etching depth which is equal to or less than a depth at which threshold intensity of the exposure light is saturated as an etching depth is increased.

The forming of the depressions may comprise verifying an optimum etching depth, based on simulated values of the threshold intensity by increasing the etching depth of the transparent substrate. The verifying of the optimum etching depth is performed by controlling an incidence angle of the exposure light, controlling critical dimensions of the depressions, changing an exposure light source, or changing the shape of the depressions.

In forming the depressions, the etching depth of the depressions may be less than the wavelength of the exposure light or may be equal to or less than a depth at which the ratio of a first light to a zero light (A₁/A₀) peaks in a near field image of the photo mask.

In accordance with the present invention, when the transparent substrate of the photo mask is etched to a specific depth, the mask topology effects enhance the contrast of the mask by diffraction and diffusion of the light at the etched sidewalls.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view of a conventional binary mask and a near field image thereof;

FIG. 2 is a schematic view of a conventional attenuated phase shift mask;

FIG. 3 is a schematic view of a photo mask according to the present invention, and a near field image thereof;

FIGS. 4A through 4D are sectional views illustrating a process of fabricating the photo mask of FIG. 3;

FIG. 5 is a graph comparing the ratio of A₁/A₀ in the near field image of the photo mask of the present invention and the conventional photo masks;

FIG. 6 is a view for explaining how the optical performance is enhanced by the sidewall effect in the photo mask according to the present invention;

FIG. 7 is a graph of the ratio of A₁/A₀ to the phase of normal incident light in the photo mask according to the present invention;

FIG. 8 is a graph of the ratio of A₁/A₀ to the phase of off-axis light at 5 degrees in the photo mask according to the present invention;

FIG. 9 is a graph of the ratio of A₁/A₀ to the phase of off-axis light at 10 degrees in the photo mask according to the present invention;

FIG. 10 is a graph of the ratio of A₁/A₀ to the phase of off-axis light at 15 degrees in the photo mask according to the present invention; and

FIG. 11 is a graph of threshold intensity with respect to etching depth of a transparent substrate in the photo mask according to the present invention.

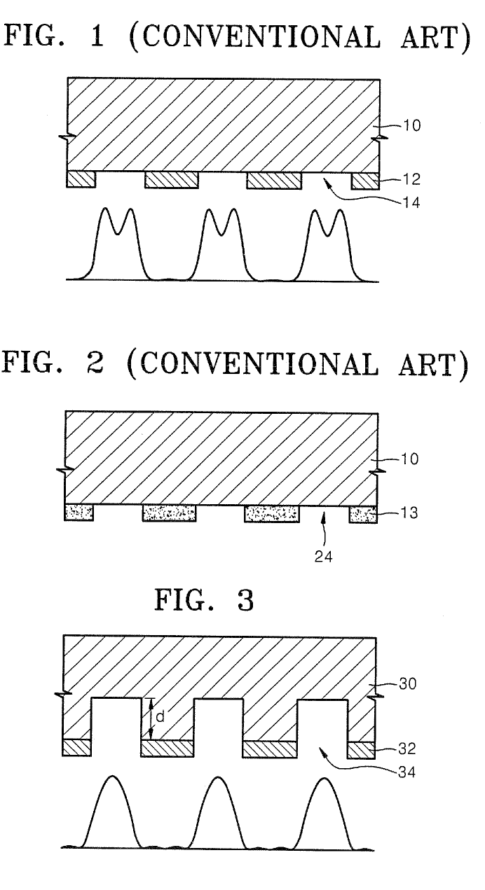

### DETAILED DESCRIPTION OF THE INVENTION

The present invention will now be described more fully with reference to the accompanying drawings, in which preferred embodiments of the invention are shown. This invention may, however, be embodied in many different forms, and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification. When one layer is described as being positioned on or above another layer or a substrate, the layer may be positioned to be directly in contact with the other layer or the substrate, or a third layer may be positioned therebetween.

FIG. 3 is a schematic view of a photo mask according to an embodiment of the present invention, and a schematic view of a near field image when light passes through the mask.

In FIG. 3, the photo mask according to the present invention comprises: a substrate having transparency to transmit an exposure light, for example, a transparent substrate 30 formed of quartz; and a light shielding layer which blocks the exposure light, for example, a light shielding layer 32 composed of chromium. The light shielding layer 32 define apertures through which the exposure light is transmitted. The shape of the aperture defines the pattern image to be transferred. A pattern of depressions 34 is formed, corresponding to the pattern of the light shielding layer 32. The depressions 34 have vertical sidewalls created by uniformly etching parts of the transparent substrate 30 to an etching depth (d) that are aligned with sidewalls of the apertures formed within the light shielding layer pattern 32.

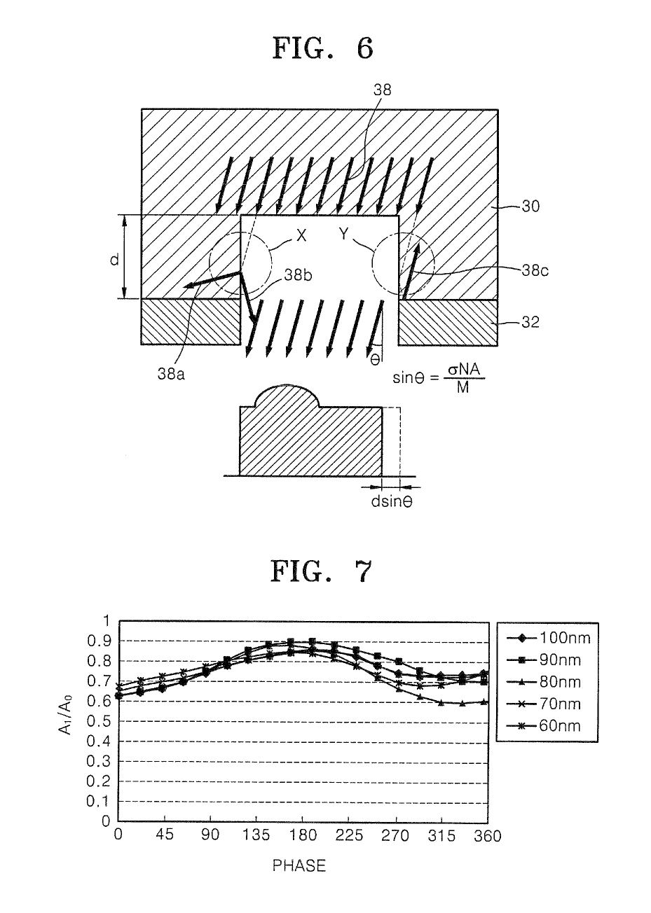

A comparison of the conventional binary mask of FIG. 1 with that of the present invention, implemented in a preferred embodiment as shown in FIG. 3, illustrates several differences. First, the photo mask according to the present invention comprises additional patterns of depressions 34 formed within the transparent substrate, unlike the binary mask where the transparent substrate is unetched. Also, when compared to the photo mask of the invention, the binary photo mask results in an aerial image in the boundary of the light shielding layer 12 that is not clear and the image in the middle of the aperture 14 (shown by the dip in FIG. 1) that is not desirable. In comparison, the photo mask according to the present invention results in an improved aerial image—e.g. regular peaks—thought to be caused in main part by the scattering and diffraction process of the light occurring at the sidewalls of the depressions 34 (see, e.g., FIG. 6 and resulting discussion). As a first order beam becomes closer to a zero order beam in the aerial image, a background value decreases, thereby enhancing the contrast of the mask.

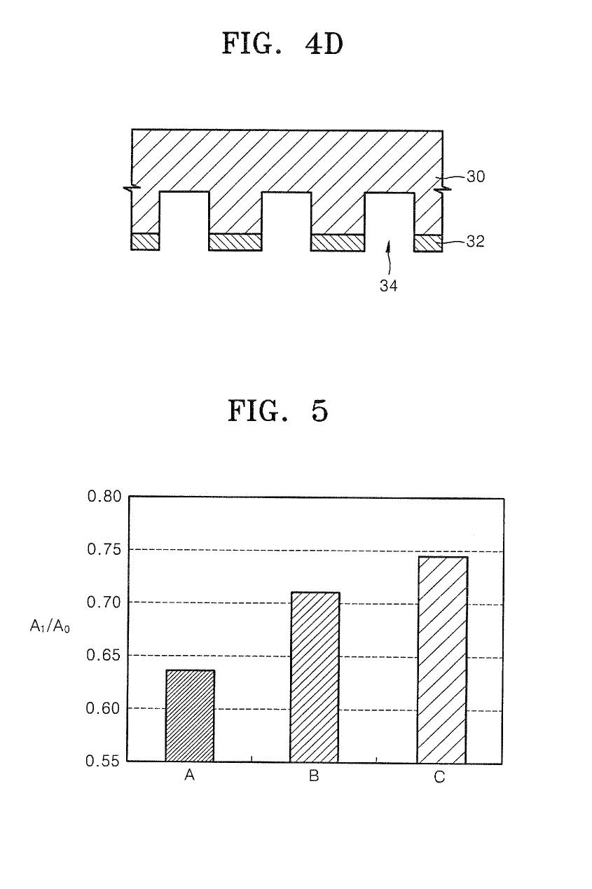

FIG. 5 is a graph comparing the ratio of A₁/A₀ in the near field image of the photo mask of the present invention and of that in conventional photo masks. For this comparison, Applicants used an exposure light source KrF having a wavelength of 248 nm, and a light shielding layer pattern having a line/space of 140 nm/140 nm. Applicants further used a simulation tool called ‘TOP0’.

In FIG. 5, ‘A’ is a thin film mask which is ideally two-dimensional, ignoring the thickness of the light shielding layer, ‘B’ is the conventional binary mask of FIG. 1, and ‘C’ is the photo mask according to an embodiment of the present invention, in which the depth of the depression (34 of FIG. 3) is 244 nm. As shown in FIG. 5, the ratio of a first order light to a zero order light in the near field image (A₁/A₀) is increased in the present invention photo mask compared to the ideal thin film mask or the conventional binary mask. Accordingly, the contrast is greatly enhanced compared to the conventional art. That is, since the light is scattered at the sidewalls of the depressions 34 in the inventive photo mask, the intensity of the light passing through the photo mask is decreased compared to the conventional binary mask. However, as the minimum intensity (Iₘₐₓ) decreases even more than the maximum intensity (Iₘᵢₙ), the resulting contrast C (C=(Iₘₐₓ−Iₘᵢₙ)/(Iₘₐₓ+Iₘᵢₙ)) using the inventive photo mask can be increased by overdosing during an exposure process.

FIG. 6 illustrates how the contrast is improved by the sidewall effect in the photo mask according to the present invention. Using an off-axis illumination system, the photo mask is exposed to light at an incidence angle (θ). And unlike when the exposure light is vertically incident on the mask, an effective space is changed by the shadowing effect resulted from the topology of the mask.

As shown in FIG. 6, with light incident on the mask from right to left, parts of an incident light 38 are totally internally reflected on the right sidewall (Y) of the depression 34, and then shielded by the light shielding layer 32, as indicated by reference numeral 38c. As a result, the effective transmission width of depression 34 and aperture becomes smaller by “dsinθ”. On the left sidewall (X) of the depression 34, parts of the incident light 38 are diffracted at the sidewall of the transparent substrate 30 and then shielded by the light shielding layer 32, as indicated by reference numeral 38a. But most of the incident light 38 is reflected from or diffused at the sidewall and passes through the aperture between the light shielding layer 32, as indicated by reference numeral 38b. Even though the effective space area is reduced by the off-axis illumination, the exposure dose which is transmitted by the diffusion or reflection of the light at the sidewalls of the depression 34 is increased as illustrated by the raised bump at the lower position in FIG. 6. Accordingly, the ratio of the first order light to the zero order light (A₁/A₀) is increased, and consequently the contrast of the photo mask is increased. In FIG. 6, ‘d’ represents the etching depth, and sinθ=σNA/M (wherein σ represents a coherence factor, ‘NA’ represents the number of apertures, and ‘M’ represents the magnification of a lens).

As illustrated in FIG. 6, as the etching depth (d) of the depression 34 is greater, the contrast is increased. Also, the optimum energy needed to transfer a pattern image of the photo mask, e.g. an exposure dose, is changed.

To enhance the contrast and obtain the optimum exposure dose, it is necessary to optimize the depth of the depression 34. For this purpose, the inventors of the present invention simulated the ratio of A₁/A₀, by controlling the incidence angle of the incident light relative to the line/space pattern and the critical dimensions (CD) of the line/space pattern and varying the depth of the depression 34. ArF having a wavelength of 193 mn was used as the exposure light source. The critical dimensions of the pattern were set to 60 nm, 70 nm, 80 nm, 90 nm and 100 nm.

FIG. 7 is a graph of the ratio of A₁/A₀ to the phase of normal incident light in the photo mask according to the present invention.

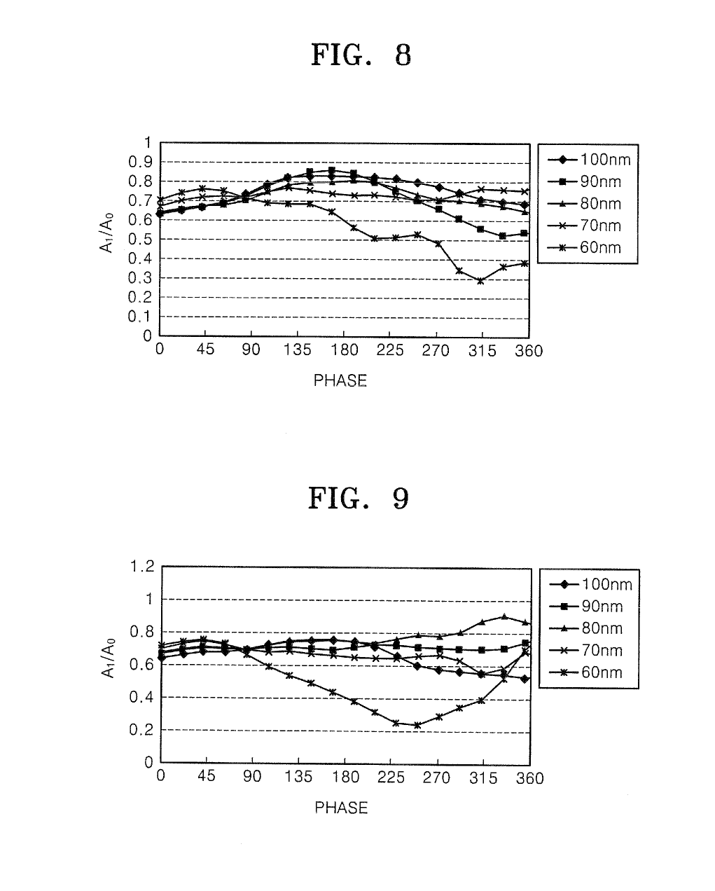

FIG. 8 is a graph of the ratio of A₁/A₀ to the phase of off-axis light at 5 degrees.

FIG. 9 is graph of the ratio of A₁/A₀ to the phase of off-axis light at 10 degrees.

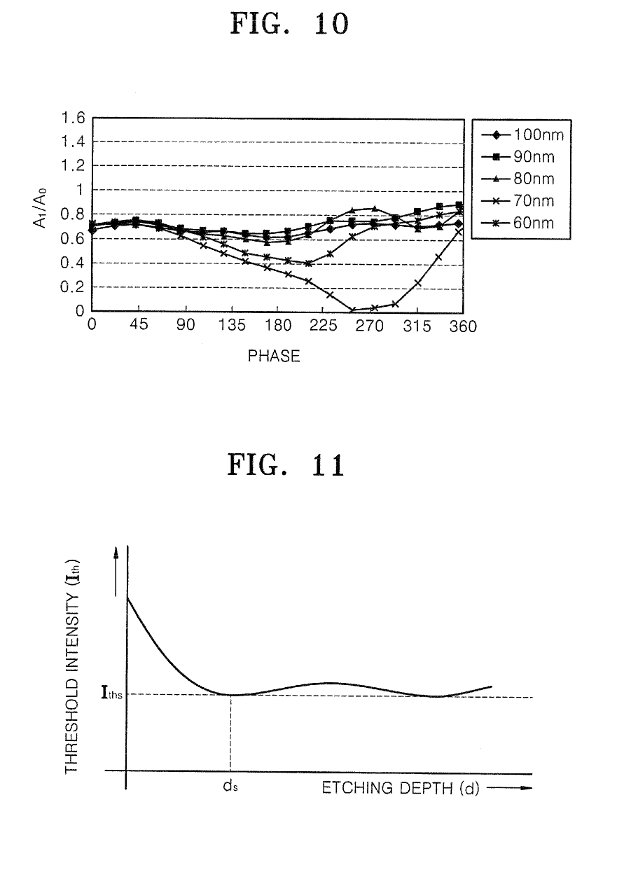

And FIG. 10 is a graph of the ratio of A₁/A₀ to the phase of off-axis light at 15 degrees.

In each graph, the phase of the horizontal axis corresponds to the depth of the depression 34 resulting from etching and removing parts of the transparent substrate. In the ArF light source, a phase of 1 degree responds to 9.56 Å. That is, in each graph, the wavelength λ of the exposure light corresponds to a phase of 180 degrees (2λ corresponds to the phase of 360 degrees) and corresponds to the etching depth of 1720 Å (that is, 180×9.56 Å=1720 Å).

Referring to the graph of FIG. 7 showing the result of the normal incident light, the ratio of the first order light to the zero order light in the near field image reaches a peak at about 180 degrees, at which the etching depth (d) of the depression 34 is equal to the wavelength of the exposure light. While the phase changes from zero to the wavelength of the exposure light, the ratio of A₁/A₀ progressively increases, and then progressively decreases when passing through the peak. That is, the contrast of the mask progressively increases up to the peak but the contrast characteristic deteriorates after passing through the peak.

Upon comparing FIGS. 7 through 10, as the incidence angle of the incident light is increased, the ratio of A₁/A₀ is generally shifted in the direction in which the phase becomes low under the wavelength of the exposure light. That is, as the critical dimensions of the pattern become smaller, the peak is shifted towards a lower phase. For example, in FIG. 9 in which the incidence angle is 10 degrees, when the critical dimensions of the pattern are 60 nm or 70 nm, the peak is shifted to a phase of about 45 degrees. This compares to the results shown in FIG. 7 where using no off-axis illumination results in a peak of 180 degrees at the 60 nm or 70 nm critical dimensions.

In FIG. 7 in which the angle of incidence of the exposure light is zero, the ratio of A₁/A₀ peaks at about the phase corresponding to the wavelength of the exposure light. Therefore, in the present invention, the etching depth of the depression 34 may be at least less than the wavelength of the exposure light. When the incidence angle of the exposure light is increased, since the peak is shifted towards a lower phase, the etching depth of the depression 34 may be less. Further, and to maximize resolution of the mask within a permissible range, the etching depth may be set to the point where the ratio of A₁/A₀ peaks.

As described, the contrast of the mask is increased within the limited range as the etching depth of the depression 34 is increased. However, to transfer a pattern image with high resolution, it is required to set the optimum exposure dose.

FIG. 11 is a graph of threshold intensity with respect to the etching depth (d) of the depression 34 in the photo mask according to the present invention. In FIG. 11, the horizontal axis represents the etching depth (d) and the vertical axis represents the threshold intensity (Iₜₕ). The threshold intensity is the intensity of the exposure light at the position corresponding to the critical dimensions of the pattern in the aerial image graphs. As illustrated in FIG. 11, as the etching depth of the depression 34 increases, the threshold intensity progressively decreases and becomes saturated at a certain point. That is, the threshold intensity progressively decreases as the etching depth changes from zero to the depth of saturation (dₛ). However, at the depth of saturation (dₛ), the threshold intensity nearly has a saturation value (Iₜₕₛ). Then, as the etching depth is increased beyond the depth at which saturation first occurs (dₛ), the threshold intensity varies slightly but is nearly saturated.

The fact that the threshold intensity increases as shown in FIG. 11 means that the energy required for transferring the pattern image with high resolution, e.g. the exposure dose, needs to be increased. This also means that the exposure dose increases progressively up to the point at which the threshold intensity is saturated. Accordingly, after the point of saturation, the exposure dose is unnecessary, serving only to increase the exposure time and lower productivity. In the present invention, the etching depth of the depression may be equal to or less than the depth of the point at which the threshold intensity is first saturated, e.g. point dₛ.

The inventors of the present invention surveyed the optical performance of the photo mask while varying the mask patterns, to determine the optimum etching depth according to the kind of mask pattern. Table 1 shows the results of this survey.

TABLE 1
Optical Performance of Photo Masks

| | Exposure Latitude | | | DOF(μm) | | | MEEF | | |
|---|---|---|---|---|---|---|---|---|---|
| | [lower # = more efficient] | | | [higher # = more efficient] | | | [lower # = more efficient] | | |
| Pattern | A1 | A2 | A3 | A1 | A2 | A3 | A1 | A2 | A3 |
| Active | 2.0 | 1.6 | 2.0 | 0.25 | 0.2 | 0.2 | 3.4 | 4.1 | 3.2 |
| Gate | 2.4 | 1.6 | 2.4 | 0.4 | 0.4 | 0.4 | 3.1 | 2.6 | 3.9 |
| Line | | | | | | | | | |
| SAC | 2.7 | 2.2 | 2.5 | 0.3 | 0.3 | 0.3 | 6.9 | 5.5 | 5.9 |
| Bit | 1.8 | 2.0 | 2.4 | 0.35 | 0.35 | 0.4 | 2.7 | 3.7 | 3.5 |
| Line | | | | | | | | | |
| RP | 3.8 | 2.4 | 3.1 | 0.2 | 0.2 | 0.25 | 5.4 | 6.7 | 4.5 |

Table 1 illustrates the results of tests across different circuit pattern types using various photo masks. The various pattern types were formed during fabrication of a 92 nm node DRAM and include such circuit types as an active pattern, a gate line pattern, a self-aligned contact (SAC) pattern, a bit line pattern, or a resist poly (RP) pattern. Exposure latitude, depth of focus (DOF) and the mask error enhancement factor (MEEF) are surveyed for each of these patterns and for each test photo masks used. The subjects to be compared are ‘A1’ which is a halftone phase shift mask having a transparency of 6% (6% HT-PSM), ‘A2’ which is a photo mask according to the present invention, having a depression etching depth of a 90 degree phase, and ‘A3’ which is another photo mask according to the present invention, having an depression etching depth of a 130 degree phase. The exposure light source is ArF.

In Table 1, the exposure latitude indicates a change in the critical dimensions of a pattern depending on a change in the exposure dose. As the exposure latitude becomes smaller, the photo mask is more efficient. The DOF indicates a permissible range of the depth of focus. As the DOF becomes greater, the photo mask is more efficient. The MEEF indicates a change in the critical dimensions of a wafer depending on a change in the critical dimensions of the mask. As the MEEF becomes smaller, the photo mask is more efficient.

From the results shown in Table 1, the line/space type patterns (e.g. gate line and bit line) generally have similar performance to the phase shift mask at the etching depth of a 90 degree phase, and the island type patterns (e.g. active, SAC and RP) have optimum optical performance at the etching depth of a 130 degree phase.

Therefore, in preferred use, an optimum etching depth must be selected for each mask pattern rather that using a fixed etching depth for all circuit pattern types. For this purpose, the wavelength of the exposure light source, the incidence angle of the incident light, the critical dimensions of the patterns, and the proper exposure dose are to be taken into account.

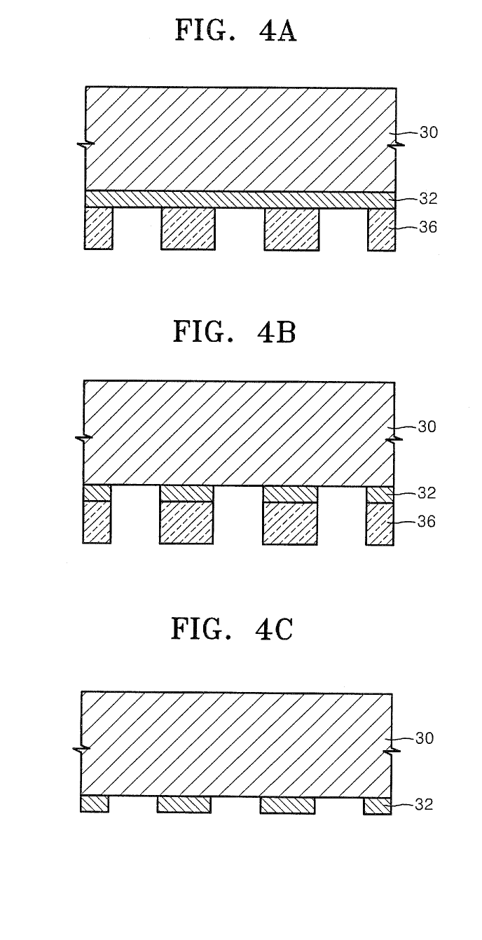

FIGS. 4A through 4D are sectional views illustrating a process of fabricating the photo mask of FIG. 3.

In FIG. 4A, a light shielding layer 32 is formed by depositing chromium, as by sputtering, on a transparent substrate 30 made of quartz. A resist for electron-beam exposure is applied to the light shielding layer 32 by spin coating. After the resist is dried and pre-baked, a mask pattern 36 in a line/space pattern type, which has predetermined critical dimensions, is formed by the electron-beam exposure and subsequent development.

In FIG. 4B, a pattern of the light shielding layer 32 is formed by using the mask pattern 36 as an etching mask and selectively removing the light shielding layer 32 exposed under the mask pattern 36 by reactive ion etching, thereby exposing parts of the transparent substrate 30. In FIG. 4C, the mask pattern 36 remaining on the pattern of the light shielding layer 32 is removed by wet etching. The mask pattern 36 may be later removed after it is used as the etching mask, together with the pattern of the light shielding layer 32, during the etching process of the transparent substrate 30.

In FIG. 4D, parts of the transparent substrate 30 are etched by using the pattern of the light shielding layer 32 as an etching mask, thereby forming patterns of depressions 34. The etching of the transparent substrate 30 is performed using, for example, an ArF excimer laser, so that the sidewalls of the depressions 34 are nearly vertical and each depression 34 has a uniform etching depth.

There are three primary advantages of the photo mask constructed and implemented according to the present invention. First, the inventive photo mask gives increased contrast and productivity by using a suitable exposure dose. Second, the photo mask can be fabricated using a relatively simple process. And third, the photo mask does not exhibit problems associated with phase shift masks.

While the present invention has been particularly shown and described with reference to exemplary embodiments thereof, it will be understood by those of ordinary skill in the art that various changes in form and detail may be made therein without departing from the spirit and scope of the present invention as defined by the following claims.

For example, in the embodiment of the present invention, KrF or ArF are used as the exposure light source. However, the exposure light source is not limited to KrF or ArF. G-line or I-line, which have a greater wavelength than KrF or ArF, or F₂, which has a shorter wavelength than KrF or ArF, may be used as the exposure light source. In the embodiment, the transparent substrate is made of quartz (SiO₂), but may also be made of other transparent materials, for example, calcium fluoride (CaF₂) or magnesium fluoride (MgF₂). In the embodiment, the light shielding layer is formed of chromium, but may also be formed of chromium oxide (CrOx), tungsten silicon (W—Si), or the like, which are capable of shielding light.

Further, the photo mask according to the present invention is usable for both the normal incident illumination system and the off-axis illumination system. The photo mask has greater benefits when used for the off-axis illumination system, e.g. with incident light having a 0˜15 degrees incidence angle.

What is claimed is:

1. A photo mask, comprising:
a transparent substrate;
a light shielding layer pattern formed on the transparent substrate having apertures through which the transparent substrate is exposed; and
depressions extending into the transparent substrate and having sidewalls aligned with the apertures.

2. The photo mask of claim 1, wherein the depressions extend into the transparent substrate to a depth at which a threshold intensity of light exposed through the photo mask is first saturated.

3. The photomask of claim 1, wherein the depressions extend into the transparent substrate to a depth equal to or less than a wavelength of light exposed through the photo mask during a photolithography process.

4. The photo mask of claim 1, wherein the etching depth of the depressions is equal to or less than a depth at which the ratio of a first order light to a zero order light (A₁/A₀) peaks in a near field image of the photo mask.

5. The photo mask of claim 3, wherein the light exposed through the photo mask has any one of G-line, I-line, KrF, ArF and F₂ as an exposure light source.

6. The photo mask of claim 1, wherein the transparent substrate is formed of any one of quartz (SiO₂), calcium fluoride (CaF₂) and magnesium fluoride (MgF₂).

7. The photo mask of claim 1, wherein the light shielding layer pattern pattern is formed of any one of chromium, chromium oxide (CrOx) and tungsten silicon (W—Si).

8. The photo mask of claim l, wherein the depressions have vertical sidewalls corresponding to sidewalls of the light shielding layer pattern.

9. The photo mask of claim 1, wherein the depressions correspond to line/space type patterns.

10. The photo mask of claim 1, wherein the depressions correspond to island type patterns.

11. The photo mask of claim 1, wherein the depressions have critical dimensions (CD) which are equal to or less than a wavelength of light exposed through the photo mask.

12. The photo mask of claim 11, wherein the critical dimensions of the depressions are 100 nm or less.

13. A method of fabricating a photo mask, comprising:
forming a light shielding layer pattern, which blocks an exposure light, on a transparent substrate having transparency to the exposure light; and
using the light shielding layer pattern as a mask, forming depressions within the transparent substrate with sidewalls aligned with the light shielding layer pattern.

14. The method of claim 13, further including passing the exposure light at an angle through an exposed top of the transparent substrate so that the exposure light passes into the depressions and reflects or diffuses from the sidewalls of the depressions.

15. The method of claim 13, further including forming the depressions with vertical sidewalls and to a uniform depth.

16. The method of claim 15, wherein the step for forming the depressions includes etching the transparent substrate using an excimer laser.

17. The method of claim 13, wherein the step of forming the depressions includes verifying an optimum etching depth, based on simulated values of the threshold intensity, by increasing the etching depth of the transparent substrate.

18. The method of claim 17, wherein the verifying of the optimum etching depth is performed by controlling an incidence angle of the exposure light.

19. The method of claim 17, wherein the verifying of the optimum etching depth is performed by controlling critical dimensions of the depressions.

20. The method of claim 17, wherein the verifying of the optimum etching depth is performed using any one of G-line, I-line, KrF, ArF and F₂ as an exposure light source.

21. The method of claim 13, wherein the step of forming the depressions includes etching the transparent substrate to an etching depth less than the wavelength of the exposure light.

22. The method of claim 13, wherein the step of forming the depressions includes etching the transparent substrate to an etching depth equal to or less than a depth at which the ratio of a first order light to a zero order light (A₁/A₀) peaks in a near field image of the photo mask.
